(19) United States
(12) Patent Application Publication
(10) Pub. No.: US 2010/0296537 A1
(43) Pub. Date: Nov. 25, 2010

(54) OPTICAL COMPONENT AND METHOD OF MANUFACTURING THEREOF

(76) Inventor: Teruhisa KOTANI, Osaka (JP)

Correspondence Address: BIRCH STEWART KOLASCH & BIRCH, PO BOX 747, FALLS CHURCH, VA, 22040-0747, US

(21) Appl. No.: 12/717,691

(22) Filed: Mar. 4, 2010

(30) Foreign Application Priority Data
May 19, 2009 (JP) 2009-120544

(51) Int. Cl. H01S 5/02; H01L 21/50

(52) U.S. Cl. 372/43.01; 438/26; 257/E21.499

(57) ABSTRACT

An optical component includes a supporter and a semiconductor laser device. The supporter has a metal wiring layer formed over the substrate and a fusing metal layer formed on the metal wiring layer. The semiconductor laser device includes an electrode and stacked semiconductor films including an active layer. A protrusion is formed on one of the supporter and the semiconductor laser device, and the end face of the protrusion is in area contact with the other one of these components. The metal wiring layer and the electrode are integrated with each other via the fusing metal layer, at a location different from the protrusion.

### CROSS REFERENCE TO RELATED APPLICATION

The present application claims priority from Japanese Patent Application No. 2009-120544, which was filed on May 19, 2009, the disclosure of which is herein incorporated by reference in its entirety.

### BACKGROUND OF THE INVENTION

1. Field of the Invention

The present invention relates to an optical component having a semiconductor laser device and a method of manufacturing thereof.

2. Description of the Related Art

One approach that has recently drawn much attention is to form an optical component by placing an optical device made of compound semiconductor or the like on a supporter such as a substrate. Examples of the optical component include optically-assisted magnetic recording apparatuses and multi-wavelength laser devices. Such optical components require highly accurate alignment in the optical coupling of the optical device and another device. For example, a multi-wavelength laser device may be arranged so that the light sources of respective laser devices are close to one another and light beams having respective wavelengths are coupled to each other by a single lens. In this case, the light beams having different wavelengths may not be optimally coupled to the lens when the alignment of the laser devices is not accurate enough.

As regards the alignment in the in-plane direction (xy direction), relatively high accuracy is achievable by an optical method such as image recognition of alignment marks formed by a semiconductor process such as lithography. On the other hand, in the height direction (z direction), alignment marks cannot be formed on the side surfaces of substrates by a semiconductor process such as lithography, because the substrate supporting the optical device is thin. It is therefore difficult to achieve optical alignment in the height direction of semiconductor laser devices.

An example of the formation of an optical component is recited in U.S. Pat. No. 7,447,7669 and “AlGaInN/AlGa/InP Two-Wavelength Laser Diodes Fabricated by Water-Level Transferring Technique” (Jpn. J. Appl. Phys. 43 (2004) pp. L136-L138) by Miyachi et al. A multi-wavelength semiconductor laser device 500 recited in this document is, as shown in FIG. 17, arranged so that a red semiconductor laser device 501 and a blue semiconductor laser device 502 are aligned with each other by optical alignment in the in-plane direction (xy direction), whereas in the height direction (z direction) the devices are mechanically aligned with each other by adjusting the pressure, and then bonded with each other by means of a metal adhesive layer 503. The metal adhesive layer 503 made of tin is solid in room temperatures and is liquidated at a melting temperature or higher. The red semiconductor laser device 501 and the blue semiconductor laser device 502 are arranged to sandwich the metal adhesive layer 503 heated at least the melting temperature and the components are pressed from the outside. As a result the red semiconductor laser device 501 and the blue semiconductor laser device 502 are bonded with each other as the devices forms eutectic bonding with the metal adhesive layer 503.

An optical terminal apparatus 600 recited in Japanese Unexamined Patent Publication No. 77634/1995 (Tokukaihei 7-77634) and U.S. Pat. No. 5,671,315 includes a semiconductor laser diode 601 and a substrate 602 as shown in FIG. 18. The semiconductor laser diode 601 is provided with an n-type electrode 607, a p-type electrode 606, an adhesive layer 608, and two V-shaped grooves 603. The substrate 602 has two V-shaped protrusions 604. The substrate 602 is coated with an insulating film 605. As the V-shaped grooves 603 receive the protrusions 604, the semiconductor laser diode 601 is aligned with the substrate 602 in all of the x, y, and z directions, and these components are bonded with each other.

### SUMMARY OF THE INVENTION

In the multi-wavelength semiconductor laser device 500 recited in Miyachi et al., the pressure required for desired alignment in the z direction varies in accordance with the shape of the surface of each of the red semiconductor laser device 501 and the blue semiconductor laser device 502 and the configuration of the films. It is therefore difficult in the z direction to achieve highly precise and repeatable alignment.

An optical terminal apparatus 600 recited in Japanese Unexamined Patent Publication No. 77634/1995 (Tokukaihei 7-77634) requires two V-shaped grooves 603 and two V-shaped protrusions 604, each of which has a triangular shape, to be formed on a semiconductor laser diode 601 and a substrate 602, respectively. Forming such triangular grooves and protrusions by dry etching of a typical semiconductor process is very complicated. Specifically, it is necessary to carry out anisotropic etching such as wet chemical etching. For example, since the (111) surface of Si substrate is exposed by an alkaline solution such as KOH, it is possible to form a triangular shape with an apex angle of about 54 degrees by a (001) surface substrate. However, most of the materials allowing anisotropic etching are crystalline materials. It is therefore difficult to precisely form triangular shapes by anisotropic etching, when a polycrystalline material such as ceramic or an amorphous material is used. Even if the semiconductor is made of a crystalline material, the aforesaid method is not executable when, as the device characteristics vary in accordance with the plane directions, the plane direction optimal for the device is different from the plane direction with which the formation of a triangular shape by anisotropic etching is possible.

In addition to the above, even if the V-shaped grooves 603 and the V-shaped protrusions 604 are successfully formed, they must precisely fit each other, otherwise an external force applied to the optical terminal apparatus 600 may result in the formation of power concentration on a particular part of the protrusion 604, thereby causing damage on the part and allowing the semiconductor laser diode 601 to be peeled off from the substrate 602.

An object of the present invention is to provide an optical component and a method of manufacturing thereof, which component is advantageous in that the alignment in the direction in which a semiconductor laser device opposes a supporter is highly precisely and easily achieved, and the semiconductor laser device is not easily peeled off from the supporter.

An optical component according to the present invention includes a supporter and a semiconductor laser device supported by the supporter. The supporter includes a substrate, a metal wiring layer formed over the substrate, and a fusing metal layer formed on the metal wiring layer. The semiconductor laser device includes: stacked semiconductor films including an active layer; and an electrode formed on the stacked semiconductor films. One of the supporter and the semiconductor laser device has a protrusion and an end face of the protrusion is in area contact with the other one of the supporter and the semiconductor laser device. The metal wiring layer is integrated with the electrode via the fusing metal layer, at a location different from the protrusion.

A method of manufacturing an optical component according to the present invention, which includes a supporter and a semiconductor laser device supported by the supporter, includes the steps of: (i) forming the supporter; (ii) forming the semiconductor laser device; and (iii) joining the supporter with the semiconductor laser device. The step (i) includes sub-steps of: (a) forming a metal wiring layer over the substrate; and (b) forming a fusing metal layer on the metal wiring layer. The step (ii) includes sub-steps of: (c) stacking a plurality of semiconductor films including an active layer; (d) on the semiconductor films, forming a ridge which includes an electrode and confines light in an in-plane direction of the semiconductor films; and (e) forming a protrusion on the semiconductor films, the protrusion being higher than the ridge. In the sub-step (e), the protrusion is formed in such a way that, when the semiconductor laser device is disposed with respect to the supporter to cause an end face of the ridge to contact the fusing metal layer, the protrusion is distanced from the supporter by a distance shorter than the thickness of the fusing metal layer. In the step (iii), the supporter and the semiconductor laser device are heated to a temperature higher than a melting temperature of the fusing metal layer while the semiconductor laser device is disposed with respect to the supporter to make the end face of the ridge contact the fusing metal layer and the supporter and the semiconductor laser device are pressed against each other, with the result that the metal wiring layer is integrated with the electrode via the fusing metal layer and the end face of the protrusion is in area contact with the supporter.

### BRIEF DESCRIPTION OF THE DRAWINGS

Other and further objects, features and advantages of the invention will appear more fully from the following description taken in connection with the accompanying drawings in which:

FIG. 1 is a longitudinal section of an optical component according to First Embodiment of the present invention.

FIG. 2 is a perspective view of a semiconductor laser device in the optical component of FIG. 1.

FIG. 3 is a perspective view of a supporter in the optical component of FIG. 1.

FIG. 4 is a longitudinal section of the semiconductor laser device and the ceramic substrate in the joining step which is carried out in the manufacture of the optical component of FIG. 1.

FIG. 5 is a flowchart of the manufacturing process of the optical component of FIG. 1.

FIG. 6 is a longitudinal section of an optical component according to Second Embodiment of the present invention.

FIG. 7 is a perspective view of a semiconductor laser device in the optical component of FIG. 6.

FIG. 8 is a longitudinal section of an optical component according to Third Embodiment of the present invention.

FIG. 9 is a perspective view of a semiconductor laser device in the optical component of FIG. 8.

FIG. 10 is a longitudinal section of an optical component according to Fourth Embodiment of the present invention.

FIG. 11 is a perspective view of a second semiconductor laser device in the optical component of FIG. 10.

FIG. 12 is a longitudinal section of a semiconductor laser device and a second semiconductor laser device which are used in the joining step in the manufacture of the optical component of FIG. 10.

FIG. 13 is a perspective view of an optical component according to Fifth Embodiment of the present invention.

FIG. 14 is a perspective view of a supporter in the optical component of the FIG. 13.

FIG. 15 is an enlarged perspective view of a near-field light generator and its surroundings, which is formed on the semiconductor laser device in the optical component of FIG. 13.

FIG. 16 is an enlarged perspective view of a near-field light generator and its surroundings, which is formed on the semiconductor laser device of a modification of Fifth Embodiment of the present invention.

FIG. 17 is a cross section of a multi-wavelength semiconductor laser device recited in Miyachi et al.

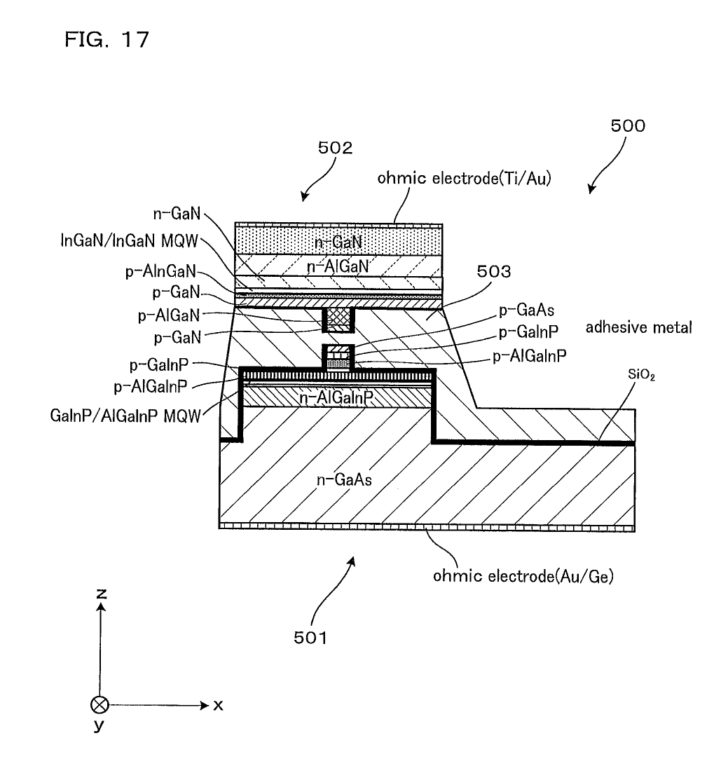

FIG. 18 is a cross section of an optical terminal apparatus recited in U.S. Pat. No. 5,671,315.

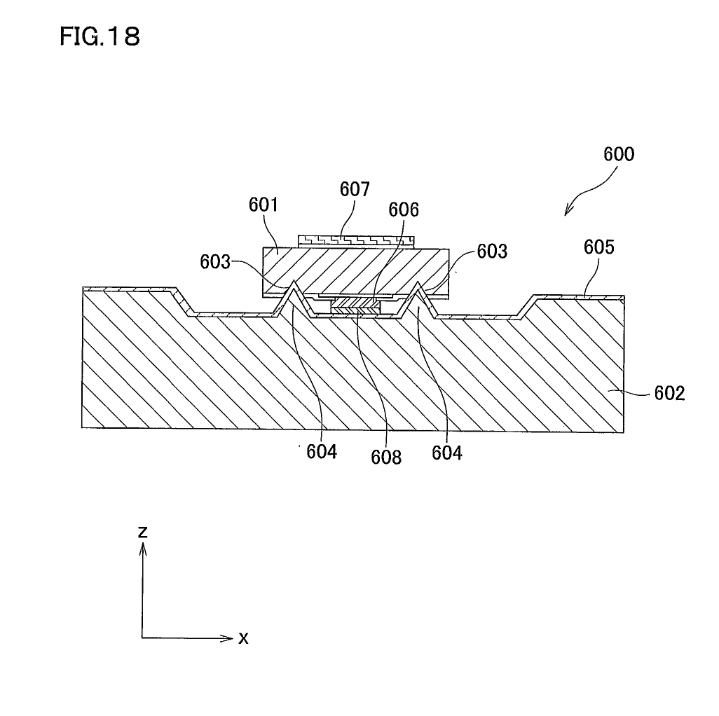

### DESCRIPTION OF THE PREFERRED EMBODIMENTS

### First Embodiment

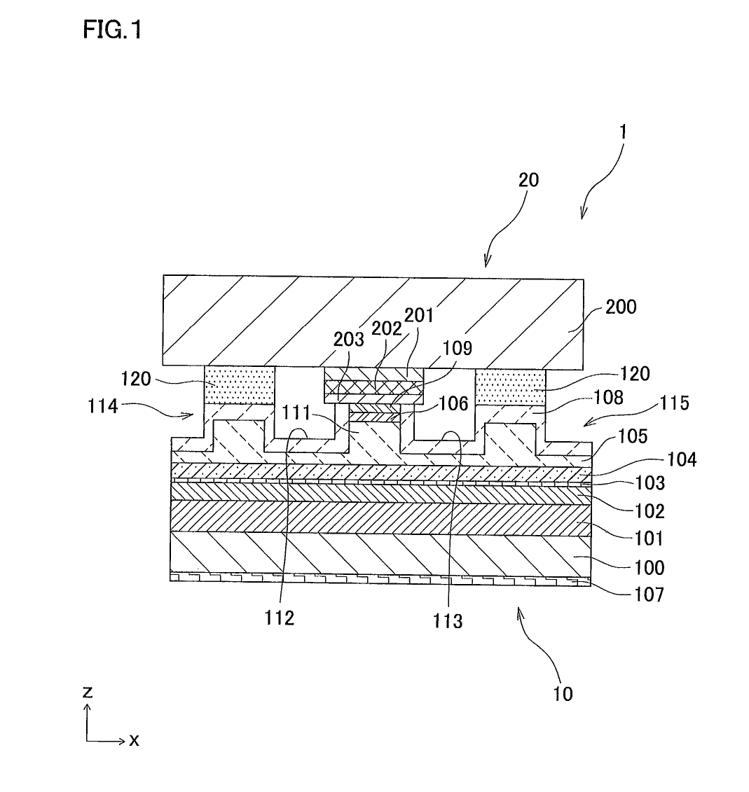

The following will describe First Embodiment of the present invention with reference to FIG. 1 to FIG. 4.

<Overall Structure>

As shown in FIG. 1, an optical component 1 includes a semiconductor laser device 10 and a supporter 20 which are joined with each other in the height direction (z direction).

<Semiconductor Laser Device>

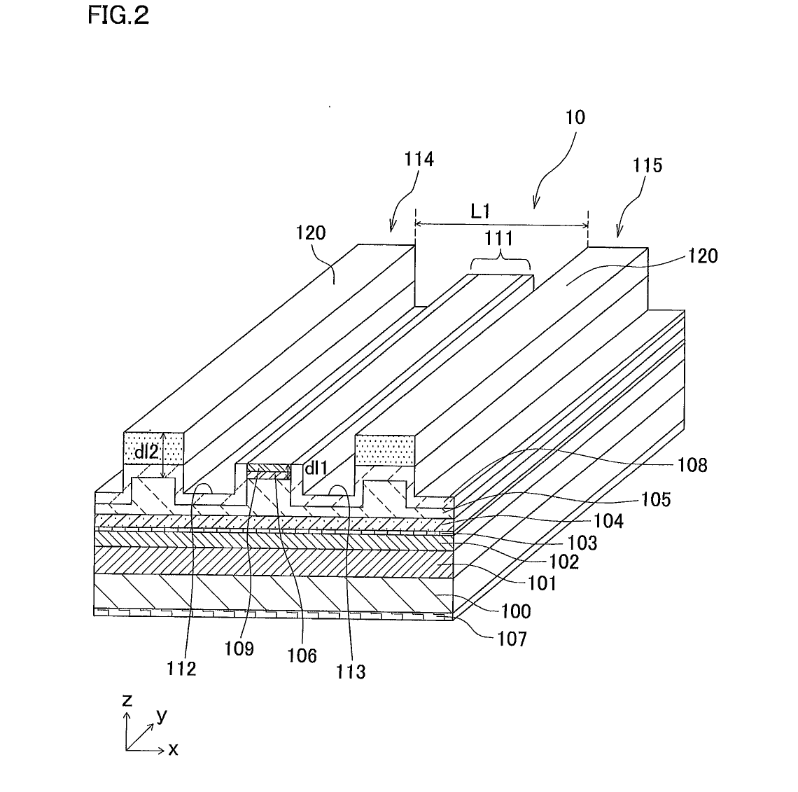

The semiconductor laser device 10 will be described first. As shown in FIG. 1 and FIG. 2, the semiconductor laser device 10 consists of an n-type electrode 107, a semiconductor substrate 100, an n-type cladding layer 101, an n-type guiding layer 102, an active layer 103, a p-type guiding layer 104, a p-type cladding layer 105, and an insulating film 108. Grooves and protrusions are formed on the upper surface of the p-type cladding layer 105. On a part of the p-type cladding layer 105 which part is included in a later-described ridge 111, a p-type electrode 106 and an adhesive layer 109 are formed as parts of the ridge 111. On a part of the p-type cladding layer 105 which part is included in a later-described height adjustment components 114 and 115, height adjustment films 120 are formed with the insulating film 108 interposed therebetween.

The semiconductor laser device 10 has a ridge-type waveguide structure. In this semiconductor laser device 10, two grooves 112 and 113 are formed by a process including dry etching so that the ridge 111 is formed. The ridge 111 protrudes toward a later-described fusing metal layer 203, and confines light in the in-plane direction, i.e. xy direction of stacked semiconductor films (in the present embodiment, the semiconductor films indicate the n-type electrode 107, the n-type cladding layer 101, the n-type guiding layer 102, the active layer 103, the p-type guiding layer 104, and the p-type cladding layer 105). Further in the semiconductor laser device 10, protruding height adjustment components 114 and 115 are formed to neighbor the ridge 111 over the grooves 112 and 113 in the x direction. The end faces of the height adjustment components 114 and 115 are flat and in parallel to the in-plane direction of the semiconductor layers constituting the semiconductor laser device 10. The end faces of the height adjustment component 114 and 115 are in area contact with the lower surface of a substrate 200 which is included in the supporter 20.

The materials of the respective layers constituting the semiconductor laser device 10 are different from one another according to required specifications (e.g. emission wavelength and output and lasing thresholds). For example, a laser device emitting red laser having an emission wavelength 650 nm is arranged as follows: the semiconductor substrate 100 is made of gallium arsenide; the n-type cladding layer 101 is made of n-(AlxGa1-x)1-yInyP (x=0.7,y=0.49); the n-type guiding layer 102 is made of n-(AlxGa1-x)1-yInyP (x=0.5,y=0.49); the active layer 103 has a quantum well structure of InxGa1-xP (x=0.45) well layer/(AlxGa1-x)1-yInyP (x=0.5,y=0.49) barrier layer; the p-type guiding layer 104 is made of p-(AlxGa1-x)1-yInyP (x=0.5,y=0.49); and the p-type cladding layer 105 is made of p-(AlxGa1-x)1-yInyP (x=0.7,y=0.49).

These layers are formed by crystal growth used for manufacturing typical crystal thin films for semiconductor laser devices. Examples of the crystal growth include metalorganic vapor phase epitaxy (MOVPE) and molecular beam epitaxy (MBE).

The p-type electrode 106 is typically a titanium/platinum/gold multi-layer film, and the n-type electrode 107 is an AuGe/nickel/gold multi-layer film. These films are typically formed by thermal evaporation or electron beam deposition.

The grooves 112 and 113 do not reach the surface of the active layer 103. In other words, between the bottom surfaces of the grooves 112 and 113 and the top surface of the active layer 103, other semiconductor layers (p-type guiding layer 104 and p-type cladding layer 105) remain. This structure in which grooves are formed in a semiconductor layer deposited on the active layer 103 is termed non-buried ridge structure.

A part of the p-type cladding layer 105 which part is included in the ridge 111 and a part of the p-type cladding layer 105 which part is included in the height adjustment components 114 and 115 are at the same height. The ridge 111 and the height adjustment components 114 and 115 extend in the y direction in a parallel manner, and are substantially identical in length.

As discussed above, on the part of the p-type cladding layer 105 included in the ridge 111, the p-type electrode 106 is formed. The n-type electrode 107 is formed on a surface of the substrate 100 which surface is opposite to the surface where the n-type cladding layer 101 is formed. The insulating film 108 made of SiN or ZrO constitutes the bottom surfaces of the grooves 112 and 113, the side surfaces of the ridge 111, and the side surfaces and top surfaces of the height adjustment components 114 and 115. The adhesive layer 109 formed on the p-type electrode 106 is a titanium/gold multi-layer film. The adhesive layer 109 is used to be alloyed with a later-described fusing metal layer 203 of the supporter 20, and the surface film to contact the fusing metal layer 203 is preferably a gold film.

The titanium film in the titanium/gold multi-layer film prevents the atom of the fusing metal layer 203, e.g. tin atom, from diffusing in the semiconductor laser device 10. The film deposited on the gold film in the adhesive layer 109 may be made of a material different from titanium, on condition that the diffusion prevention above is achieved. Also, if the diffusion does not influence on the properties of the semiconductor laser device 10, the adhesive layer 109 may include only the gold film. Furthermore, if the surface film of the p-type electrode 106 is made of a material which can be alloyed with the fusing metal layer 203, the adhesive layer 109 is unnecessary because the p-type electrode 106 functions as the adhesive layer 109.

The insulating height adjustment films 120 are formed on the parts of the insulating film 108 included in the height adjustment components 114 and 115. The height adjustment films 120 may be made of the same material as the insulating film 108. If this is the case, the insulating film 108 may function as the height adjustment films 120.

The p-type electrode 106 is formed only at an upper portion of the ridge 111, and hence it does not exist at an upper portion of the height adjustment components 114 and 115. A current is therefore injected exclusively to a lower portion of the ridge 111. As a current sufficient to cause lasing is applied, the active layer 103 which is in a region overlapped with the ridge 111 in a plan view does not absorb laser light, whereas the active layer in regions overlapped with the grooves 112 and 113 and the height adjustment components 114 and 115 in a plan view absorbs laser light.

In addition to the above, because of the grooves 112 and 113, the ridge 111 is optically separated from the height adjustment components 114 and 115 by air which has an extremely low refractive index. For this reason, in the n-type guiding layer 102, active layer 103, and p-type guiding layer 104, light is confined in the region below the ridge 111. Furthermore, since the ridge 111 and the height adjustment components 114 and 115 are formed at different parts of the semiconductor laser device 10, the light confinement by the ridge 111 is not influenced by the height adjustment components 114 and 115. In addition to this, a high degree of design freedom is achieved because the ridge 111 and the height adjustment components 114 and 115 can be individually formed.

The semiconductor laser device 10 has a cavity structure. The both ends of the cavity structure in the y direction are provided with facet mirrors (not illustrated) for reflecting light.

The above-described materials and configuration of the films of the semiconductor laser device 10 are merely exemplary in nature, and are suitably selectable in accordance with a desired emission wavelength, a desired output, and the like.

The distance in the x direction between the ridge 111 and the height adjustment components 114 and 115 is determined in accordance with a desired light confinement property in the x direction. As the distance increases, the light confinement into the ridge 111 intensifies in the x direction: however, if the semiconductor laser device 10 is warped in the xy in-plane direction, the degree of misalignment increases in the z direction. On the other hand, as the aforesaid distance decreases, the light confinement into the ridge 111 weakens in the x direction: however, misalignment in the z direction is lessened on the contrary to the above case.

In FIG. 2, the height from the top surface of the part of the p-type cladding layer 105 included in the ridge 111 to the top surface of the adhesive layer 109 (i.e. the distance in the z direction), in other words the total thickness of the p-type electrode 106 and the adhesive layer 109 is indicated as dl1. In addition to this, the height from the top surface of the part of the p-type cladding layer 105 included in the height adjustment components 114 and 115 to the top surfaces of the height adjustment films 120, in other words the total thickness of the insulating film 108 and the height adjustment films 120 in the height adjustment components 114 and 115 is indicated as dl2. Also, the distance between the height adjustment component 114 and the height adjustment component 115 in the x direction is indicated as L1. This distance L1 is longer than the width of the ridge 111 in the x direction.

<Supporter>

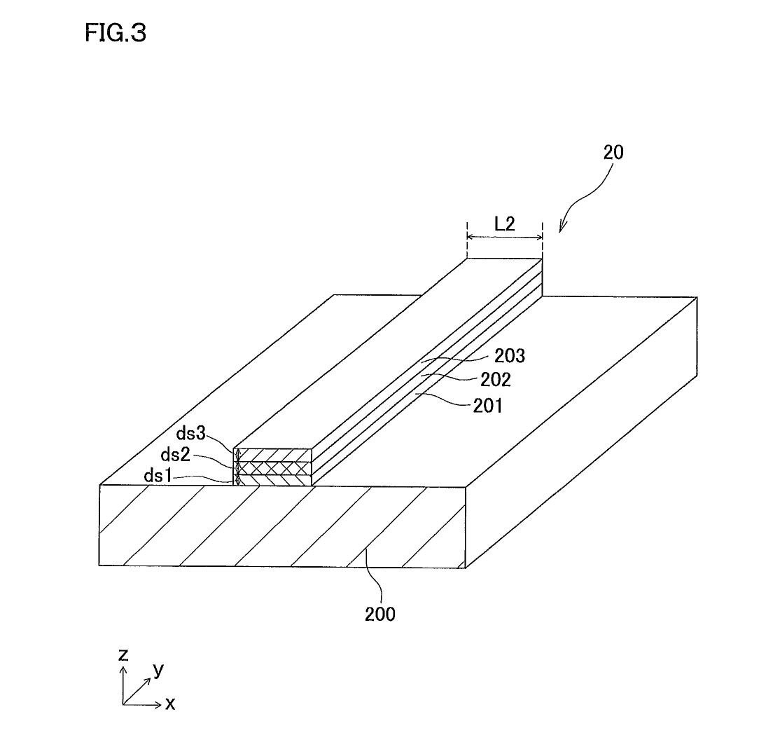

Now, the supporter 20 will be described with reference to FIG. 1 and FIG. 3. As shown in FIG. 1 and FIG. 3, the supporter 20 includes a substrate 200. On the substrate 200 are formed a metal adhesive layer 201, a metal wiring layer 202, and a fusing metal layer 203 in this order from near to far from the substrate 200.

The material of the substrate 200 is suitably determined in consideration of the purpose. For example, a substrate for heat dispersion/cooling is made of a metal material having good heat conductivity such as copper, whereas a substrate for an optical integrated circuit is made of a semiconductor material such as silicon and gallium arsenide. Alternatively, the substrate 200 may be made of an amorphous material such as glass.

The metal adhesive layer 201 made of nickel is provided for improving the adhesion between the substrate 200 and the metal wiring layer 202. Apart from nickel, the metal adhesive layer 201 may be made of materials increasing the adhesion, such as chromium, titan, and tantalum. The metal adhesive layer 201 is preferably about 15-30 nm thick.

The metal wiring layer 202 is electrically connected to the p-type electrode 106 of the semiconductor laser device 10 via the fusing metal layer 203 and the adhesive layer 109. The metal wiring layer 202 is made of a material which is good in conductivity, hardly oxidizes, has good adhesion property to the metal adhesive layer 201, and is fusible with the fusing metal layer 203. An example of such a material is gold.

The fusing metal layer 203 is a metal material for electrically and mechanically connecting (joining) the p-type electrode 106 of the semiconductor laser device 10 with the metal wiring layer 202 of the substrate 200, and is solid at room temperatures. This fusing metal layer 203 preferably fuses at a relatively low process temperature and forms an eutectic crystal with the materials of the adhesive layer 109 and the metal wiring layer 202. The most preferable material of the fusing metal layer is gold-tin alloy (mass ratio of 80% gold and 20% tin). The gold-tin alloy is widely used as a lead-free solder material because its melting temperature is only about 280 degrees and its wettability to gold is good.

The metal adhesive layer 201, the metal wiring layer 202, and the fusing metal layer 203 are formed by a widely used metal thin film formation method such as thermal evaporation and sputtering. The metal adhesive layer 201, the metal wiring layer 202 and the fusing metal layer 203 are patterned by lift-off patterning.

Provided that the thickness of the adhesive layer 201, the thickness of the metal wiring layer 202, and the thickness of the fusing metal layer 203 before the semiconductor laser device 10 is joined with the supporter 20 in the later-described joining step are respectively expressed by ds1, ds2, and ds3, the thickness of each of the insulating film 108, metal adhesive layer 201, metal wiring layer 202, and fusing metal layer 203 is represented as ds1+ds2<dl2−dl1<ds1+ds2+ds3. In other words, the height difference between the top surfaces of the adjustment films 120 and the top surface of the adhesive layer 109 is longer than the total thickness of the metal adhesive layer 201 and the metal wiring layer 202 and shorter than the total thickness of the metal adhesive layer 201, metal wiring layer 202, and the fusing metal layer 203. Furthermore, provided that the width of the fusing metal layer 203 in the x direction is L2, the inequality L2<L1 is satisfied. It is noted that the metal adhesive layer 201 and the metal wiring layer 202 of the present embodiment are equivalent to the metal wiring layer of the present invention. The metal adhesive layer 201 may be unnecessary if the metal wiring layer 202 is in close contact to the substrate 200.

As discussed layer, because the fusing metal layer 203 forms an eutectic state with the adhesive layer 109 and the metal wiring layer 202, the metal wiring layer 202 and the p-type electrode 106 are integrated with each other via the fusing metal layer 203, at a location different from the height adjustment components 114 and 115.

The optical component 1 of the present embodiment has advantages in that the alignment of the height adjustment films 120 with the substrate 200 in the z direction is highly precisely and easily done as the end faces of the height adjustment films 120 are in area contact with the substrate 200, and an external force applied to the optical component 1 is dispersed without concentrating on a particular part of the height adjustment films 120. For this reason the height adjustment films 120 are not damaged and the semiconductor laser device 10 is not easily peeled off from the supporter 20. This advantage is further enhanced because the end faces of the height adjustment films 120 are flat. The optical component 1 of the present embodiment also has advantages in that most of the height adjustment components 114 and 115 can be formed at the time of the formation of the ridge 111 by dry etching. Moreover, since the surface with high thickness accuracy, which is formed by the film deposition process, provides reference for height adjustment, the height of the light emitting point of the semiconductor laser device 10 is highly precisely positioned by a simple process and hence an optical component which excels in mass productivity and reliability is obtained.

In the present embodiment, the ridge 111 is formed by removing unnecessary parts of the p-type cladding layer 105 by dry etching. Because the part of the p-type cladding layer 105 included in the ridge 111 and the parts of the p-type cladding layer 105 included in the height adjustment components 114 and 115 are at the same height, it is possible to form the ridge 111 and the height adjustment components 114 and 115 at the same time, with the result that the manufacturing process is simplified. Moreover, the formation of the p-type cladding layer 105 which is a semiconductor layer can be done by the film deposition process, and it is therefore easy to obtain a layer having a desired thickness. In other words, since the height adjustment components 114 and 115 include the p-type cladding layer 105, the thickness of these components can be determined as desired. In this manner, the positional adjustment in the z-direction is carried out in such a way that the height adjustment components 114 and 115 formed to have desired thickness are in area contact with the substrate 200 of the supporter 20. The positional precision in the semiconductor laser device 10 is therefore very high.

<Manufacturing Process>

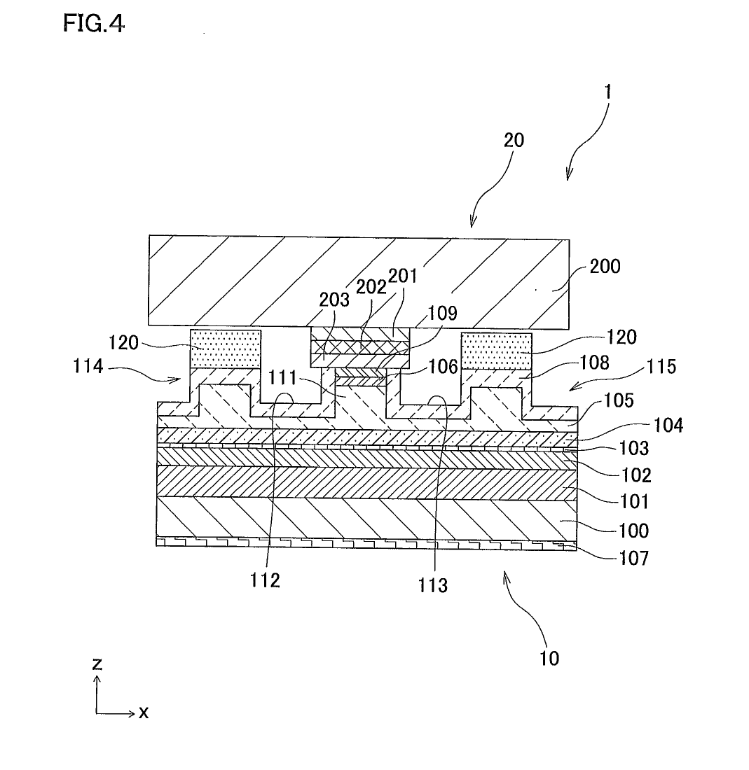

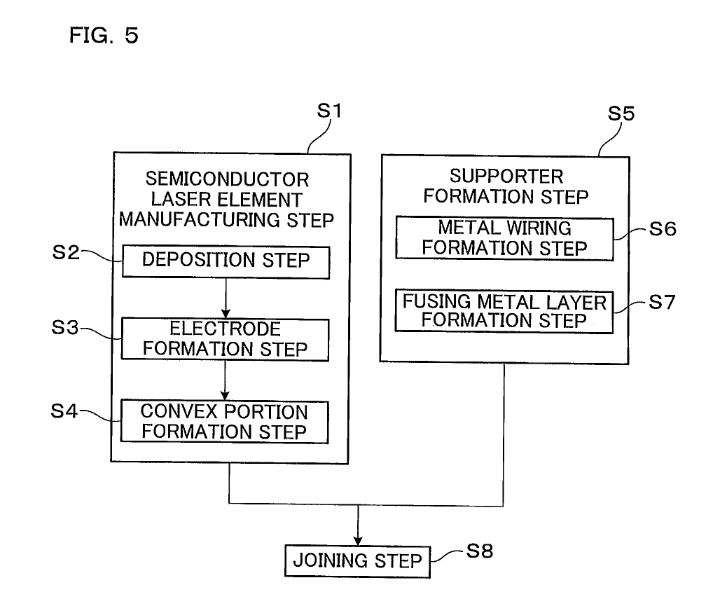

Now, the following will describe a manufacturing process of the optical component 1 with reference to FIG. 4 and FIG. 5. As shown in FIG. 5, the optical component 1 is manufactured by joining a semiconductor laser device 10 with a supporter 20, which have been manufactured by different processes.

Semiconductor Laser Device Manufacturing Step: S1

A semiconductor laser device manufacturing step will be described. First, on a semiconductor substrate 100, an n-type cladding layer 101, an n-type guiding layer 102, an active layer 103, a p-type guiding layer 104, and a p-type cladding layer 105 are formed in this order by a crystal growth method known as MOVPE or MBE (deposition step: S2). In the present embodiment, the materials are selected as follows to allow the semiconductor laser device 10 to emit 650 nm light: the semiconductor substrate 100 is made of gallium arsenide; the n-type cladding layer 101 is made of n-(AlxGa1-x)1-yInyP(x=0.7,y=0.49); the n-type guiding layer 102 is made of n-(AlxGa1-x)1-yInyP(x=0.5,y=0.49); the p-type guiding layer 104 is made of p-(AlxGa1-x)1-yInyP(x=0.5,y=0.49); and the p-type cladding layer 105 is made of p-(AlxGa1-x)1-yInyP(x=0.7,y=0.49). The active layer 103 has a quantum well structure represented as InxGa1-xP(x=0.45) well layer/(AlxGa1-x)1-yInyP(x=0.5,y=0.49) barrier layer.

Thereafter, grooves 112 and 113 are formed in the p-type cladding layer 105 by dry etching so that a ridge 111 and height adjustment components 114 and 115 are formed. As a result, the height of the top surface of the part of the p-type cladding layer 105 included in the ridge 111 (i.e. the height in the z direction in FIG. 1) is equal to the height of the top surfaces of the parts of the p-type cladding layers 105 included in the height adjustment components 114 and 115, as described above. Furthermore, at the same time as the ridge 111 is defined by forming the grooves 112 and 113, the height adjustment components 114 and 115 are formed. It is therefore possible to simplify the manufacturing process. Furthermore, since the p-type cladding layer 105 is formed by the film deposition process, it is easy to arrange the p-type cladding layer 105 to have a desired thickness. In other words, since the height adjustment components 114 and 115 include the p-type cladding layer 105, it is possible to arrange the height adjustment components 114 and 115 to have a desired thickness.

Thereafter, by thermal evaporation or electron beam deposition, a p-type electrode 106 constituted by a titan/platinum/gold multi-layer film is formed on the top surface of the part of the p-type cladding layer 105 included in the ridge 111. Furthermore, an n-type electrode 107 constituted by an AuGe/nickel/gold multi-layer film is formed on the bottom surface of the semiconductor substrate 100 (electrode formation step: S3). Subsequently, on the top surface of the p-type electrode 106, an adhesive layer 109 constituted by a titan/gold multi-layer film is formed so that the gold film is on the top surface.

Then an insulating film 108 is formed to entirely cover the exposed part of the p-type cladding layer 105 (i.e. the part which is not covered with the p-type electrode 106 and the adhesive layer 109). In the present embodiment, the thickness of the insulating film 108 is sufficiently shorter than the depth of the grooves 112 and 113, and hence the shape of each of the grooves 112 and 113 does not change over the formation of the insulating film 108. Thereafter, on the top surfaces of the parts of the insulating film 108 included in the height adjustment components 114 and 115, height adjustment films 120 are formed (convex portion formation step: S4). The top surface of the height adjustment film 120 is higher than the top surface of the adhesive layer 109 by dl2−dl1. Since the height adjustment films 120 are made of an insulating material, the top surface thereof is also insulating. It is noted that, although the upper surfaces of the height adjustment films 120 may be conductive, they are preferably insulative in order to prevent unexpected conduction. With this step, the formation of the semiconductor laser device 10 is completed.

In the semiconductor laser device manufacturing step, the height adjustment films 120 are formed so that, when the semiconductor laser device 10 is disposed with respect to the supporter 20 in such a way as to cause the adhesive layer 109 to contact the fusing metal layer 203, the height adjustment films 120 are distanced from the supporter 20 by a distance shorter than the thickness ds3 of the fusing metal layer 203.

Supporter Formation Step: S5

Now the supporter formation step will be described. First, on the surface of the substrate 200 made of a material selected in accordance with the purpose, a metal adhesive layer 201 constituted by a nickel thin film is formed to be about 15 nm-30 nm thick. The substrate 200 is made of copper, silicon, gallium arsenide, or an amorphous material such as glass, for example.

Thereafter, on the top surface of the metal adhesive layer 201, a metal wiring layer 202 made of gold is formed (metal wiring formation step: S6), and on the top surface of the metal wiring layer 202, a fusing metal layer 203 made of AuSn (mass ratio of 80% gold and 20% tin) is formed (fusing metal layer formation step: S7). The metal adhesive layer 201, the metal wiring layer 202, and the fusing metal layer 203 are formed by thermal evaporation or sputtering, and patterned by lift-off patterning. The supporter 20 is formed in this way.

As described above, in the supporter formation step the thickness of each of the insulating film 108, the metal adhesive layer 201, the metal wiring layer 202, and the fusing metal layer 203 is determined to satisfy ds1+ds2<dl2−dl1<ds1+ds2+ds3.

Joining Step: S8

Now, a step of joining the supporter 20 with the semiconductor laser device 10 will be described. As shown in FIG. 4, the supporter 20 is disposed on the semiconductor laser device 10 so that the adhesive layer 109 contacts the fusing metal layer 203. In so doing, the alignment of these components in the in-plane direction (xy direction) orthogonal to the height direction (z direction) in which the components oppose each other is carried out by typical optical alignment. For example, the alignment may be carried out in such a way that the semiconductor laser device 10 is moved while being observed from below by a microscope so that a facet mirror (not illustrated) formed on the xy plane overlaps the end face of the substrate 200.

After the alignment of the semiconductor laser device 10 and the supporter 20 in the in-plane direction, a pressure of about 10 kg/cm² is applied to them in the direction of pressing them against each other. At this moment, the adhesive layer 109 is in contact with the fusing metal layer 203, whereas the height adjustment films 120 are separated from the substrate 200 by a distance shorter than the thickness ds3 of the fusing metal layer 203.

Thereafter, the lamination of the semiconductor laser device 10 and the supporter 20 is put into an unillustrated furnace while these components are being pressurized, and the lamination is heated to a temperature not lower than the melting temperature (eutectic point) of the fusing metal layer 203. As a result, the fusing metal layer 203 is liquidized. Because the components are still being pressurized, the substrate 200 is moved downward to get close to the semiconductor laser device 10, so that the height adjustment films 120 contact the substrate 200 as shown in FIG. 1. In this way, the distance between the substrate 200 and the active layer 103 (light emitting point) of the semiconductor laser device 10 is precisely controlled by the height adjustment components 114 and 115 each having a desired thickness.

The adhesive layer 109 and the fusing metal layer 203 form eutectic bonding as they are heated to a temperature not lower than the eutectic point of the fusing metal layer 203. The metal wiring layer 202 and the fusing metal layer 203 also form eutectic bonding. After being kept at the high temperature for around 10 minutes, the lamination is annealed while still being pressurized, and the temperature then returns to room temperatures. When the temperature becomes not higher than the eutectic point during the annealing, the fusing metal layer 203 returns to solid. After the temperature completely returns to room temperatures, the pressure is removed. As a result, the metal wiring layer 202 is integrated with the p-type electrode 106 via the fusing metal layer 203, and the flat end face of the height adjustment film 120 is in area contact with the substrate 200 of the supporter 20. The semiconductor laser device 10 is joined with the supporter 20 in this way. As the metal wiring layer 202 and the n-type electrode 107 receive an electric signal from the outside, the semiconductor laser device 10 is driven.

In the mass production, each process proceeds so that many semiconductor laser devices 10 are manufactured from a single wafer. When the supporter 20 has a cleavage plane which spreads in the same direction as the unillustrated facet mirror of the semiconductor laser device 10, or when the supporter 20 is thin enough not to obstruct the cleavage formation step of the facet mirror of the semiconductor laser device 10, it is possible to carry out an alternative manufacturing process such that the steps other than the facet mirror formation are carried out in consideration of the state of the wafer, and the facet mirror is formed on the semiconductor laser device 10 by cleavage after the aforesaid joining process. A typical step of manufacturing the semiconductor laser device is carried out such that the ridges 111 are arranged in parallel like bars (i.e. laser resonators are arranged in parallel in the x direction) and cutting into each chip is then carried out by dicing.

The dicing is preferably carried out in such a way that a ridge 111 and two height adjustment components 114 and 115 are included in a single chip, for example, the cutting surfaces are located in the outer sides of the height adjustment component 114 and 115 (i.e. on the opposite side of the ridge 111) as shown in FIG. 1.

In the manufacturing process of the optical component 1 according to the present embodiment, the joining step is arranged so that the fusing metal layer 203 is fused and the supporter 20 is aligned with the semiconductor laser device 10 in the z direction so that the end face of the height adjustment film 120 is in area contact with the supporter 20. In this way, the alignment in the z direction is easily and highly precisely achieved only by forming the height adjustment films 120 which has been adjusted in height.

### Second Embodiment

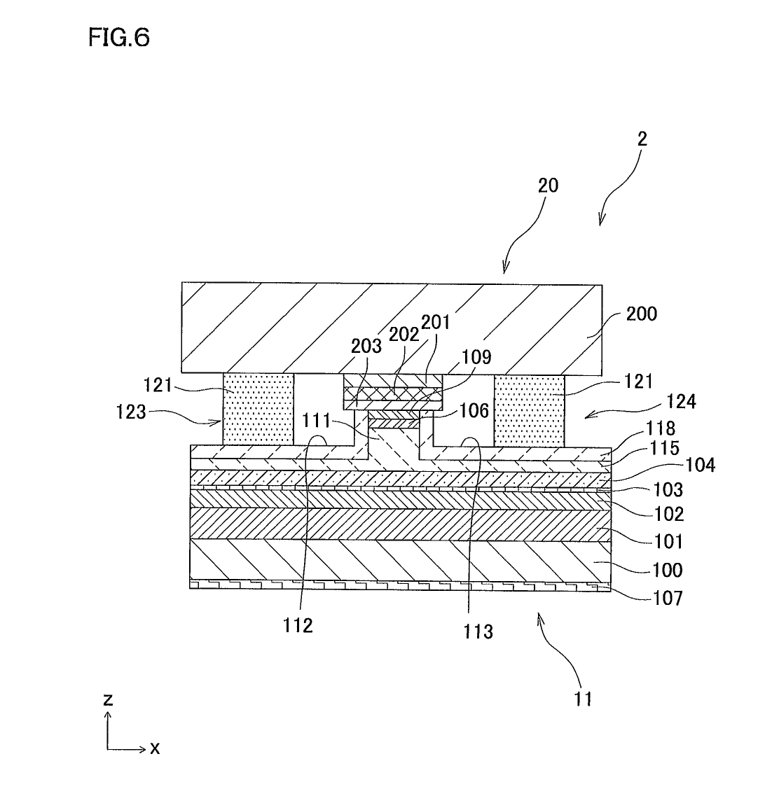

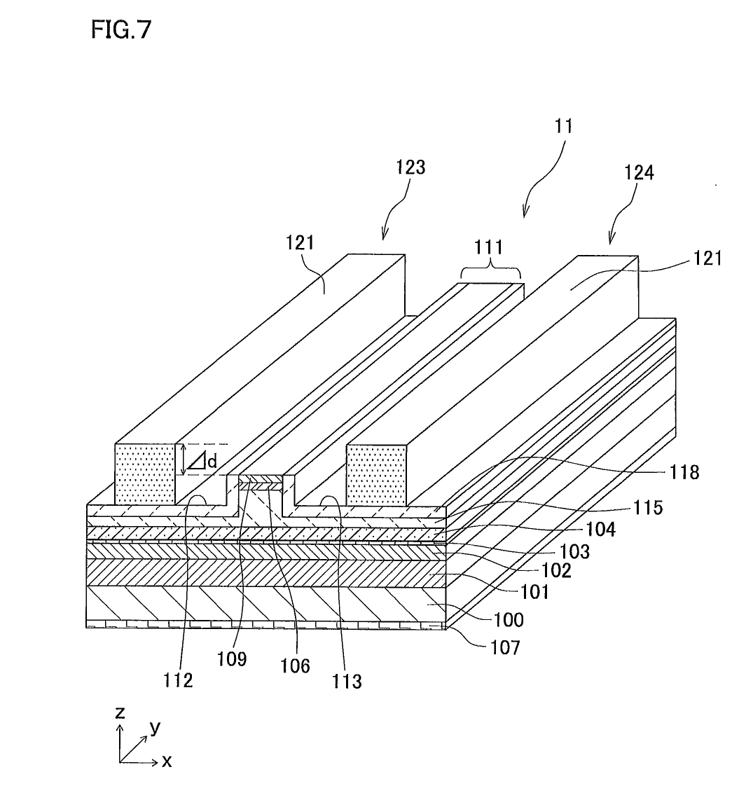

Now, Second Embodiment of the present invention will be described with reference to FIG. 6 and FIG. 7. It is noted that the same reference numerals are assigned to components having substantially identical arrangements as those of First Embodiment, and a repeated explanation is suitably avoided. As shown in FIG. 6 and FIG. 7, an optical component 2 of Second Embodiment is different from the optical component 1 of First Embodiment in the structure of the height adjustment components.

<Overall Structure>

As shown in FIG. 6, the optical component 2 includes a semiconductor laser device 11 and a supporter 20 which oppose each other in the z direction and are joined with each other. The supporter 20 is not described here because it is identical with the supporter 20 of First Embodiment.

<Semiconductor Laser Device>

The following will describe the semiconductor laser device 11 with reference to FIG. 6 and FIG. 7. As shown in FIG. 6 and FIG. 7, the semiconductor laser device 11 is arranged so that an n-type electrode 107, a semiconductor substrate 100, an n-type cladding layer 101, an n-type guiding layer 102, an active layer 103, a p-type guiding layer 104, a p-type cladding layer 115, and an insulating film 118 are deposited in this order from bottom to top. On apart of the p-type cladding layer 115 which part is included in the ridge 111, a part of the p-type electrode 106 which part is included in the ridge 111 and an adhesive layer 109 are deposited.

The semiconductor laser device 11 has a waveguide structure. In the semiconductor laser device 11, two grooves 112 and 113 sandwiching the ridge 111 are formed by a step including dry etching. The side surfaces of the ridge 111 and the surface of the p-type cladding layer 115 except where the ridge 111 is formed are entirely covered with the insulating film 118.

In the semiconductor laser device 11, furthermore, protruding height adjustment components 123 and 124 are formed to neighbor the ridge 111 over the grooves 112 and 113 in the x direction. The height adjustment components 123 and 124 are constituted by insulating height adjustment films 121. The height adjustment films 121 are preferably made of the same material of the height adjustment films 120 of First Embodiment. The end faces of the height adjustment components 123 and 124 are flat surfaces in parallel to the in-plane direction of stacked semiconductor films constituting the semiconductor laser device 11 (in the present embodiment, the semiconductor films are the n-type electrode 107, the n-type cladding layer 101, the n-type guiding layer 102, the active layer 103, the p-type guiding layer 104, and the p-type cladding layer 115). The end faces of the height adjustment components 123 and 124 are in area contact with the lower surface of the substrate 200 in the supporter 20. The height adjustment films 121 are formed, for example, in such a way that patterning by dry etching or the like is carried out after film formation by a typical method of forming insulating films such as sputtering, thermal evaporation, or CVD is conducted.

The difference Δd between the height of the top surface of the height adjustment film 121 (i.e. height in the z direction) and the height of the top surface of the ridge 111 (i.e. height in the z direction) is equivalent to dl1−dl2 in First Embodiment. Therefore the inequality ds1+ds2<Δd<ds1+ds2+ds3 is satisfied in the present embodiment. In the semiconductor laser device manufacturing step, the height adjustment films 121 are formed so that, when the semiconductor laser device 11 is disposed with respect to the supporter 20 to cause the adhesive layer 109 to contact the fusing metal layer 203, the height adjustment films 121 are distanced from the supporter 20 by a distance shorter than the thickness ds3 of the fusing metal layer 203.

The joining step in which the supporter 20 is joined with the semiconductor laser device 11 is identical with the step in First Embodiment. As shown in FIG. 7, the supporter 20 is joined with the semiconductor laser device 11 while these components are highly precisely aligned with each other by the height adjustment components 123 and 124. The process of chip formation in the mass production is not described here because it is identical with that of First Embodiment.

In the optical component 2 of the present embodiment, while the alignment in the z direction is highly precisely and easily achieved because the end faces of the height adjustment films 121 are in area contact with the substrate 200, an external force applied to the optical component 2 is dispersed without concentrating on a particular part of the height adjustment film 121. This prevents the height adjustment films 121 from being damaged and the semiconductor laser device 11 from being easily peeled off from the supporter 20. This effect is further enhanced by arranging the end faces of the height adjustment films 121 to be flat surfaces. In the optical component 2 of the present embodiment, furthermore, since the ridge 111 and the height adjustment components 123 and 124 are formed at different parts of the semiconductor laser device 11, the light confinement by the ridge 111 is not influenced by the height adjustment components 123 and 124. In addition to this, a high degree of design freedom is achieved because the ridge 111 and the height adjustment components 123 and 124 can be individually formed.

### Third Embodiment

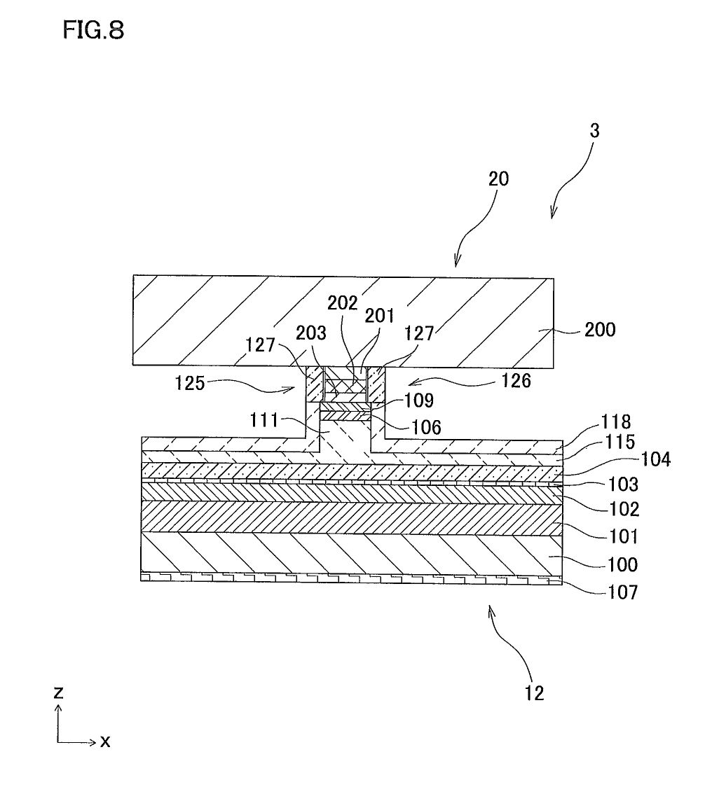

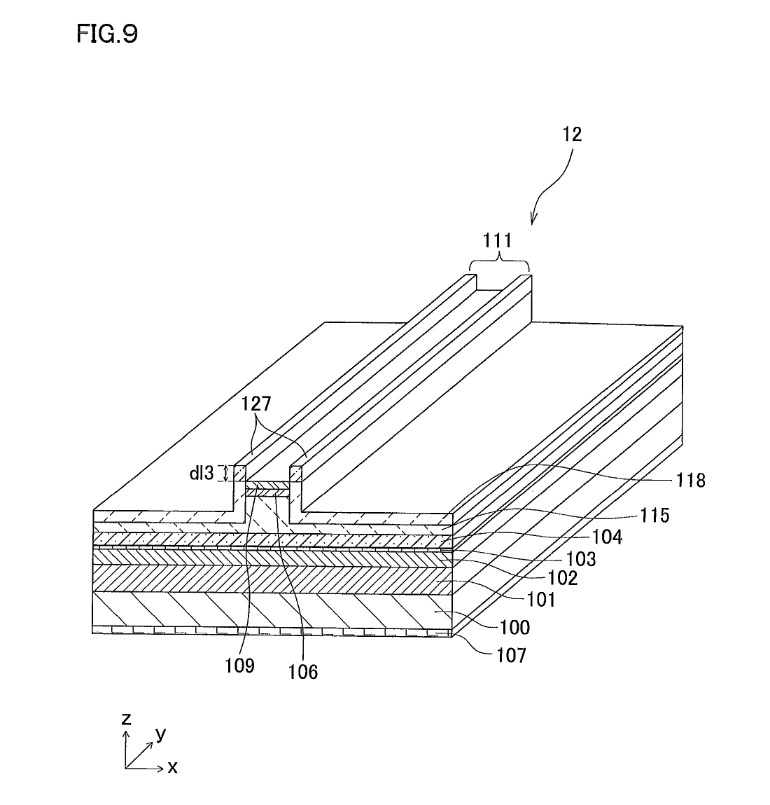

Now, the following will describe Third Embodiment of the present invention with reference to FIG. 8 and FIG. 9. It is noted that the same reference numerals are assigned to components having substantially identical arrangements as those of First Embodiment or Second Embodiment, and a repeated explanation is suitably avoided. An optical component 3 of Third Embodiment is different from the optical component 2 of Second Embodiment in terms of the structure of the height adjustment components.

<Overall Structure>

As shown in FIG. 8, the optical component 3 includes a semiconductor laser device 12 and a supporter 20 which oppose each other in the z direction and are joined each other. The supporter 20 is not described here because it is identical with the supporter 20 of First Embodiment and Second Embodiment.

<Semiconductor Laser Device>

The semiconductor laser device 12 will be described with reference to FIG. 8 and FIG. 9. As shown in FIG. 8 and FIG. 9, the semiconductor laser device 12 is arranged so that an n-type electrode 107, a semiconductor substrate 100, an n-type cladding layer 101, an n-type guiding layer 102, an active layer 103, a p-type guiding layer 104, a p-type cladding layer 115, and an insulating film 118 are deposited in this order from bottom to top. On a part of the p-type cladding layer 115 which part is included in the ridge 111, the p-type electrode 106 and the adhesive layer 109 are deposited as parts of the ridge 111.

The side surfaces of the ridge 111 and the surface of the p-type cladding layer 115 except where the ridge 111 is formed are entirely covered with the insulating film 118. At the both edges of the ridge 111 in the x direction above the p-type electrode 106 via the adhesive layer 109, height adjustment components 125 and 126 constituted by an insulating height adjustment film 127 are formed. These height adjustment components 125 and 126 extend in the direction in parallel to the direction in which the ridge 111 extends (i.e. y direction). Viewing in the direction (z direction) orthogonal to the in-plane direction of stacked semiconductor films constituting the semiconductor laser device 12 (in the present embodiment, the semiconductor films are n-type electrode 107, n-type cladding layer 101, n-type guiding layer 102, active layer 103, p-type guiding layer 104, and p-type cladding layer 115), the height adjustment components 125 and 126 partly overlap with the p-type electrode 106 of the semiconductor laser device 12. The end faces of the height adjustment components 125 and 126 are flat surfaces in parallel to the in-plane direction of the semiconductor layers. The end faces of the height adjustment components 125 and 126 are in area contact with the lower surface of the substrate 200 of the supporter 20. The height adjustment film 127 is preferably made of the same material as the height adjustment film 121 of Second Embodiment. The height adjustment films 127 are formed, for example, in such a way that patterning by dry etching or the like is carried out after film formation by a typical method of forming insulating films such as sputtering, thermal evaporation, or CVD is conducted.

The thickness dl3 of the height adjustment film 127 is equivalent to dl1−dl2 in First Embodiment and Δd in Second Embodiment. For this reason ds1+ds2<dl3<ds1+ds2+ds3 is satisfied in the present embodiment. The distance between the height adjustment films 127 in the x direction is longer than the width of the fusing metal layer 203 in the x direction. In other words, the two height adjustment films 127 are slightly distanced in the x direction from the fusing metal layer 203. In the semiconductor laser device manufacturing step, the height adjustment films 127 are formed so that, when the semiconductor laser device 12 is disposed with respect to the supporter 20 to cause the adhesive layer 109 to contact the fusing metal layer 203, the height adjustment films 127 are separated from the supporter 20 by a distance shorter than the thickness ds3 of the fusing metal layer 203.

The joining step in which the supporter 20 is joined with the semiconductor laser device 12 is identical with the step in First Embodiment or Second Embodiment. As shown in FIG. 8, the supporter 20 is joined with the semiconductor laser device 12 while these components are highly precisely aligned with each other by the height adjustment components 125 and 126. The process of chip formation in the mass production is not described here because it is identical with that of First Embodiment.

The optical component 3 according to the present embodiment in which the height adjustment components 125 and 126 are formed to partly overlap the p-type electrode 106 in the z direction has advantages in that the volume of the optical component is lower than the optical component 1 of First Embodiment and the optical component 2 of Second Embodiment.

### Fourth Embodiment

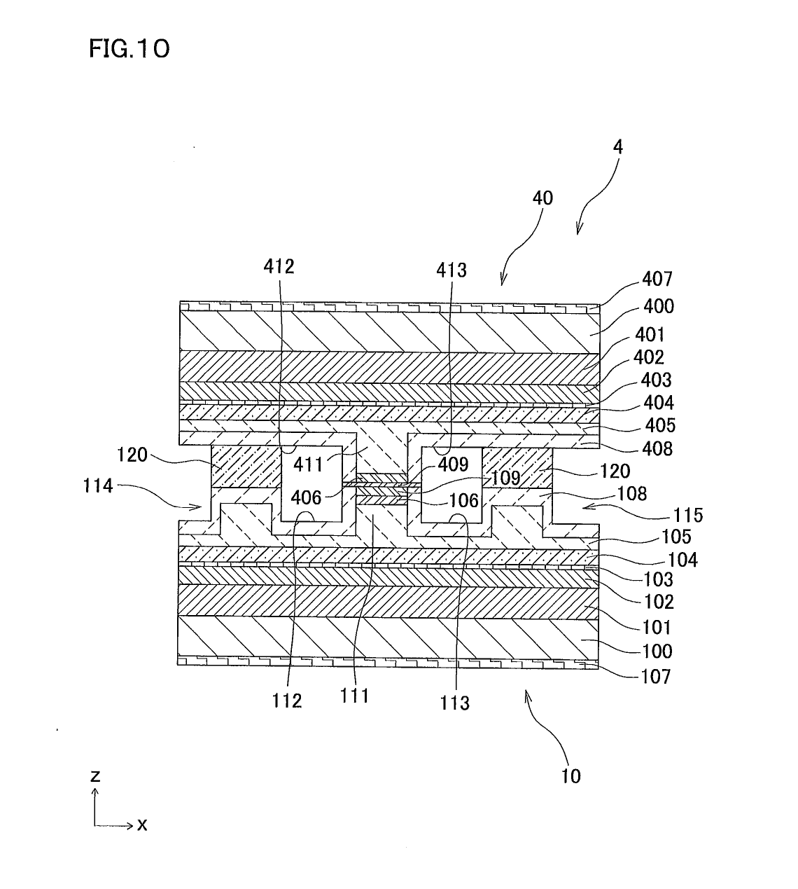

The following will describe Fourth Embodiment of the present invention with reference to FIG. 10-FIG. 12. It is noted that the same reference numerals are assigned to components having substantially identical arrangements as those of First Embodiment, and a repeated explanation is suitably avoided. An optical component 4 of Fourth Embodiment is arranged so that a semiconductor laser device which is an optical device is provided in place of the supporter 20 of First Embodiment.

<Overall Structure>

As shown in FIG. 10, the optical component 4 includes a semiconductor laser device 10 and a second semiconductor laser device 40 which oppose each other in the z direction and are joined with each other. The semiconductor laser device 10 is not described here because it is identical with the semiconductor laser device 10 of First Embodiment. A plurality of semiconductor laser devices 10 are formed on an unillustrated semiconductor wafer. A ridge 111 of the semiconductor laser device 10 extends in the direction perpendicular to the cleavage crystal plane of the material of an unillustrated semiconductor wafer.

<Second Semiconductor Laser Device>

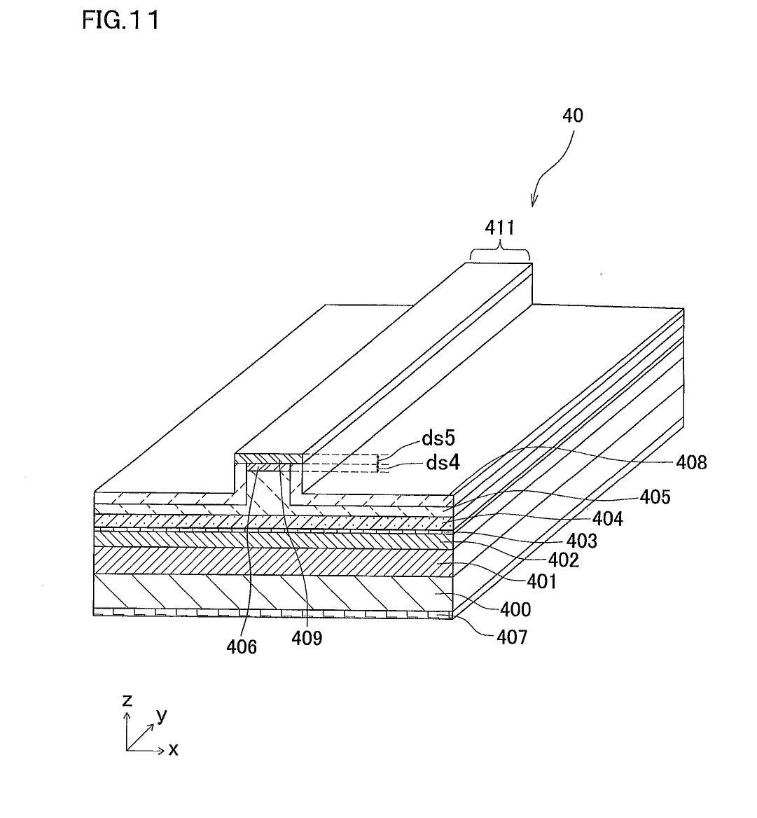

The second semiconductor laser device 40 will be described with reference to FIG. 10 and FIG. 11. Plural second semiconductor laser devices 40 are formed on an unillustrated semiconductor wafer. As shown in FIG. 10 and FIG. 11, the second semiconductor laser device 40 is arranged so that an n-type electrode 407, a semiconductor substrate 400, an n-type cladding layer 401, an n-type guiding layer 402, an active layer 403, a p-type guiding layer 404, a p-type cladding layer 405, and an insulating layer 408 are deposited in this order from bottom to top. On a below-described part of the p-type cladding layer 405 which part is included in the ridge 411, a p-type electrode 406 is formed as a part of the ridge 411.

The second semiconductor laser device 40 has a waveguide structure. In this second semiconductor laser device 40, two grooves 412 and 413 are formed by a process including dry etching to sandwich the ridge 411. The ridge 411 protrudes toward the p-type electrode 106, and confines light in the in-plane direction, i.e. xy direction of stacked semiconductor films (in the present embodiment, the semiconductor films are the n-type electrode 407, the n-type cladding layer 401, the n-type guiding layer 402, the active layer 403, the p-type guiding layer 404, and the p-type cladding layer 405). The ridge 411 extends in the direction perpendicular to the cleavage crystal plane of the material of the semiconductor wafer. The grooves 412 and 413 do not reach the surface of the active layer 403, and therefore a semiconductor layer (p-type cladding layer 405) remains in the space between the bottom surfaces of the grooves 412 and 413 and the top surface of the active layer 403. The side surfaces of the ridge 411 and a part of the surface of the p-type cladding layer 405 where the ridge 411 is not formed are entirely covered with the insulating film 408.

On the surface of the substrate 400 which surface is opposite to the surface contacting the n-type cladding layer 401, the n-type electrode 407 is formed. On the bottom surfaces of the grooves 412 and 413 and the side surfaces of the ridge 411 is formed the insulating layer 408. On the surface of the p-type electrode 406 is formed the fusing metal layer 409. This fusing metal layer 409 is a metal layer having the same function as the fusing metal layer 203 of First Embodiment, and is preferably made of gold-tin alloy (mass ratio of 80% gold and 20% tin) in the same manner as the fusing metal layer 203.

The second semiconductor laser device 40 which is a supporter emitting a different wavelength from the semiconductor laser device 10, more specifically with a wavelength of about 405 nm. In the second semiconductor laser device 40, the semiconductor substrate 400 is made of GaN, the n-type cladding layer 401 is made of n-AlxGa1-xN (x=0.1), the n-type guiding layer 402 is made of n-GaN, the active layer 403 has a quantum well structure of InxGa1-xN (x=0.12) well layer/InxGa1-xN (x=0.02) barrier layer, the p-type guiding layer 404 is made of p-GaN, and the p-type cladding layer 405 is made of p-AlxGa1-xN (x=0.1). These layers are formed by a crystal growth method such as MOVPE and MBE.

The p-type electrode 406 which is a metal wiring layer is typically a titan/platinum/gold multi-layer film and the n-type electrode 407 is typically an AuGe/nickel/gold multi-layer film. These electrodes are formed by either resistance heating thermal evaporation or electron beam deposition. The p-type cladding layer 405 and the side surfaces of the ridge 411 are entirely covered with the insulating film 408 made of SiN or ZrO. As the fusing metal layer 409 forms eutectic bonding with the adhesive layer 109 and the p-type electrode 406, the p-type electrode 106 is integrated with the p-type electrode 406 with the fusing metal layer 409 interposed therebetween. Furthermore, the flat end face of the height adjustment film 120 is in area contact with the insulating layer 408 of the second semiconductor laser device 40.

The above-described material and film construction of the second semiconductor laser device 40 are mere examples. The material and film construction can therefore be suitably changed in accordance with a desired emission wavelength, desired output, or the like.

Assuming that the thickness of the p-type electrode 406 is ds4 and the thickness of the fusing metal layer 409 is ds5 as shown in FIG. 11, ds4 and ds5 satisfy the inequality ds5<dl1−dl2<ds4+ds5.

<Manufacturing Process>

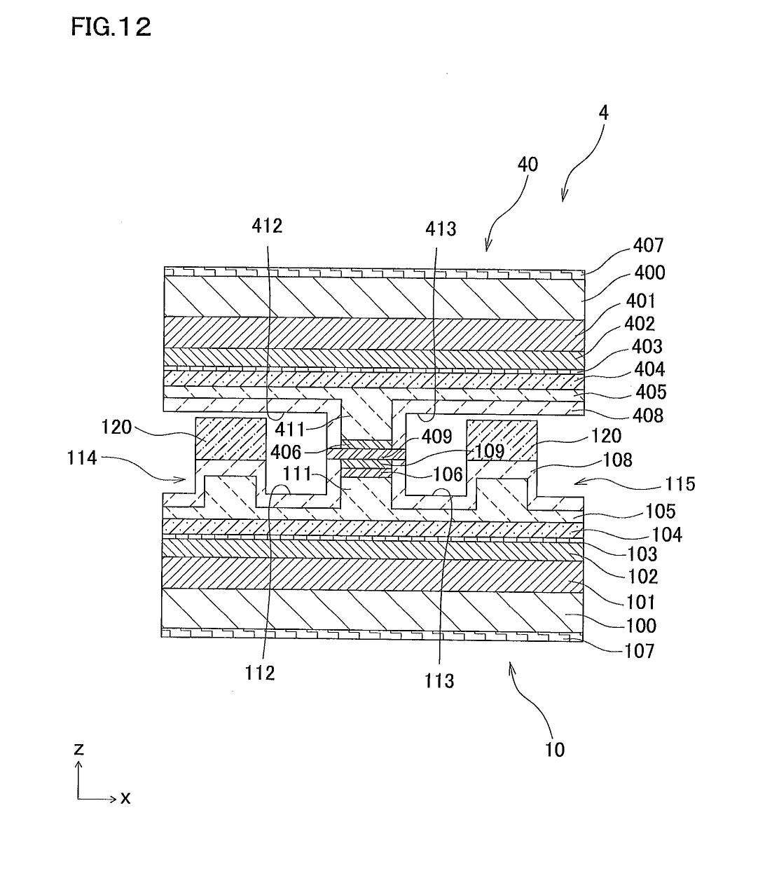

Now, a manufacturing process of the optical component 4 will be described with reference to FIG. 12.

Semiconductor Laser Device Manufacturing Step

The manufacturing process of the semiconductor laser device 10 is identical with the above-described process. In the semiconductor laser device manufacturing step, the height adjustment film 120 is formed so that, when the semiconductor laser device 10 is disposed with respect to the second semiconductor laser device 40 to cause the adhesive layer 109 to contact the fusing metal layer 409, the height adjustment film 120 is separated from the second semiconductor laser device 40 by a distance shorter than the thickness ds3 of the fusing metal layer 409. The manufacturing method of the second semiconductor laser device 40 is identical with that of the semiconductor laser device 10 except that the formation of the adhesive layer 109 and the height adjustment components 114 and 115 is omitted. Furthermore, after the fusing metal layer 409 is formed on the p-type electrode 406 by thermal evaporation or sputtering, the fusing metal layer 409 is patterned by lift-off patterning.

Joining Step

Now the step of joining the semiconductor laser device 10 with the second semiconductor laser device 40 will be described. As shown in FIG. 12, the second semiconductor laser device 40 is disposed on the semiconductor laser device 10 so that the adhesive layer 109 contacts the fusing metal layer 409. The alignment in the xy in-plane direction orthogonal to the direction in which the layers oppose each other (i.e. the z direction) is achieved by typical optical alignment. For example, the alignment in the xy-in plane is achieved by matching unillustrated orientation flats (each of which is a notch formed in a typical semiconductor wafer and indicating the plane direction of the wafer) formed in the semiconductor laser device 10 and second semiconductor laser device 40, respectively. This matching operation is carried out in such a way that, as to the ridge 111 of the semiconductor laser device 10 and the ridge 411 of the second semiconductor laser device 40, the center lines of these ridges extending in the y direction overlap each other with respect to the x direction in plan view.

After the alignment of the semiconductor laser device 10 and the second semiconductor laser device 40 in the xy in-plane direction, a pressure of about 10 kg/cm² is applied to them in the z direction to press them against each other. In this state, the adhesive layer 109 contacts the fusing metal layer 409, whereas the height adjustment film 120 is separated from the insulating film 408 by a distance shorter than the thickness ds5 of the fusing metal layer 409.

Thereafter, the lamination of the semiconductor laser device 10 and the second semiconductor laser device 40 is put into an unillustrated furnace while these components are being pressurized, and the lamination is heated to a temperature not lower than the melting temperature (eutectic point) of the fusing metal layer 409. As a result, the fusing metal layer 409 is liquidized. Because the components are still being pressurized, the second semiconductor laser device 40 is moved downward to get close to the semiconductor laser device 10, so that the height adjustment films 120 contact the insulating film 408 as shown in FIG. 12. In this way, the distance between the insulating film 408 of the second semiconductor laser device 40 and the active layer 103 (light emitting point) of the semiconductor laser device 10 is precisely controlled by the height adjustment components 114 and 115 each having a desired thickness.

The adhesive layer 109 and the fusing metal layer 409 form eutectic bonding as they are heated to a temperature not lower than the eutectic point of the fusing metal layer 409. The p-type electrode 406 and the fusing metal layer 409 also form eutectic bonding. After being kept at the high temperature for around 10 minutes, the lamination is annealed while still being pressurized, and the temperature then returns to room temperatures. When the temperature becomes not higher than the eutectic point during the annealing, the fusing metal layer 409 returns to solid. After the temperature completely returns to room temperatures, the pressure is cancelled. As a result, the p-type electrode 406 is integrated with the p-type electrode 106 via the fusing metal layer 409, and the flat end faces of the height adjustment films 120 are in area contact with the insulating film 408 of the second semiconductor laser device 40. The semiconductor laser device 10 is joined with the second semiconductor laser device 40 in this way.

The joined body formed as above is cleaved by scratching, by a diamond scriber, the end portions of the semiconductor laser devices 10 and 40 in the direction perpendicular to the ridges 111 and 411, at intervals corresponding to a desired laser resonator length, so that the facet mirror of the resonator is formed and the formation of the optical component 4 is completed. The process of chip formation in the mass production is not described here because it is identical with that of First Embodiment.

The optical component 4 of the present embodiment has advantages in that an integrated optical component 4 is realized because two semiconductor laser devices 10 and 40 are highly precisely and easily aligned while the light emitting points of the respective devices are arranged to be close to each other. Furthermore, since it becomes easy to design the optical system such as a lens for coupling sets of light emitted from the semiconductor laser devices 10 and 40 with each other, a mass-producible multi-wavelength light emitting laser device is realized. Furthermore, since the two semiconductor laser devices 10 and 40 emit light with different wavelengths, variations in produced mass-producible multi-wavelength light emitting laser devices are small.

### Fifth Embodiment

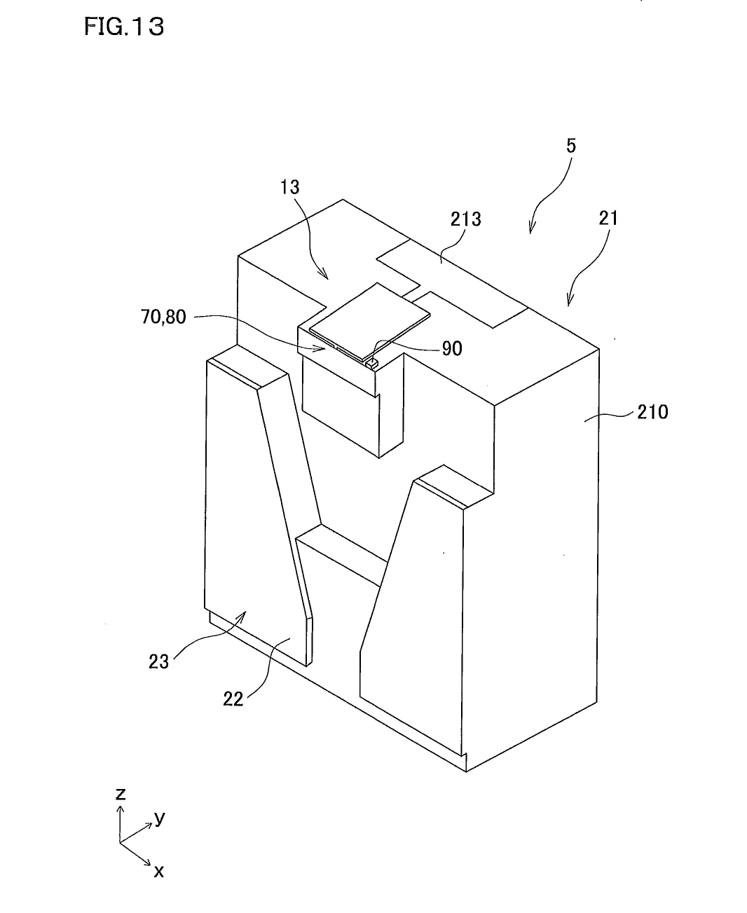

Fifth Embodiment of the present invention will be described with reference to FIG. 13-FIG. 15. It is noted that the same reference numerals are assigned to components having substantially identical arrangements as those of First to Fourth Embodiments, and a repeated explanation is suitably avoided. As shown in FIG. 13, an optical component 5 of Fifth Embodiment includes a supporter 21 mainly constituted by a ceramic substrate 210, in place of the supporter 20 of First Embodiment.

<Overall Structure>

As shown in FIG. 13, the optical component 5 includes a semiconductor laser device 13, a supporter 21, a near-field light generator 70, and a magnetic field generator 80.

<Semiconductor Laser>

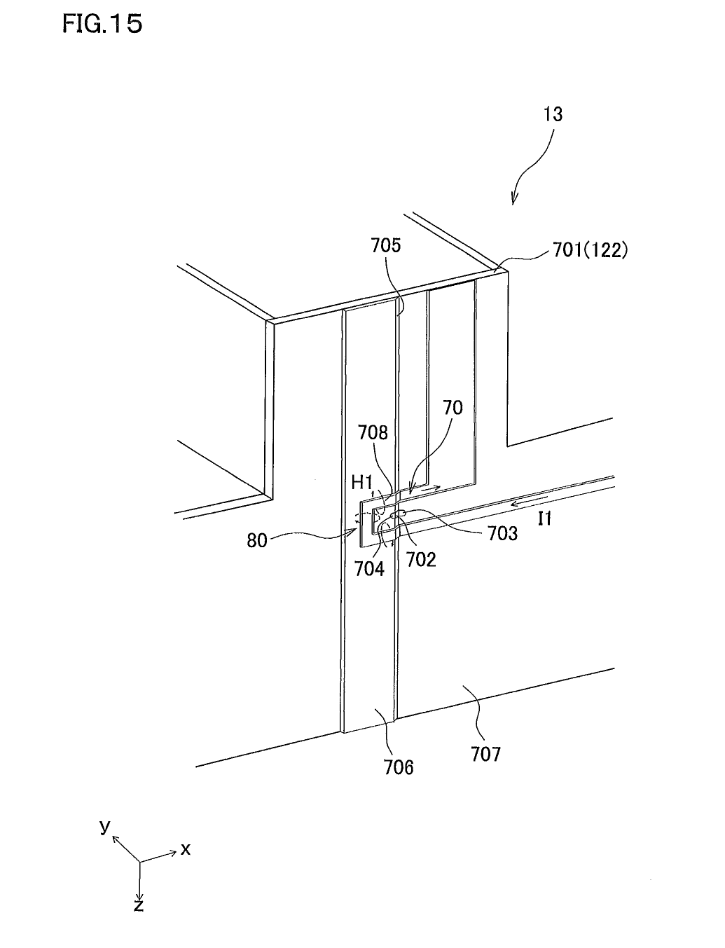

The semiconductor laser device 13 will be described first. The semiconductor laser device 13 of the present embodiment is identical with one of the semiconductor laser devices 10, 11, and 12 of above-described First to Third Embodiments. As the enlarged end face around the ridge in FIG. 15 indicates, on the surface of one facet mirror 122 of the semiconductor laser device 13 is formed an insulating film 701. On the surface of the insulating film 701 is formed a near-field light generator 70. The insulating film 701 is provided for electrically insulating a semiconductor laminated film of the semiconductor laser device 13 constituting the facet mirror 122 from the near-field light generator 70, and is transparent at least to the lasing wavelength of the semiconductor laser device 13.

The insulating film 701 preferably functions as an anti-reflection (AR) mirror. In this case, the insulating film 701 is made of a multi-layer film material such as a SiO2/ZrO multi-layer film. The thickness of the insulating film 701 may be designed by a typical interference check of multi-layer film, to arrange the reflectance for normal incidence with respect to the oscillation wavelength of the semiconductor laser device 13 to be a desired reflectance, e.g. about 5%.

The supporter 21 has a ceramic substrate 210. On the ceramic substrate 210, a metal adhesive layer (not illustrated), a metal wiring layer (not illustrated), and a fusing metal layer 213 are deposited from bottom to top. The metal adhesive layer, the metal wiring layer, and the fusing metal layer 213 are identical with the metal adhesive layer 201, the metal wiring layer 202, and the fusing metal layer 203 of the supporter 20 of First Embodiment, in terms of the materials and the structures.

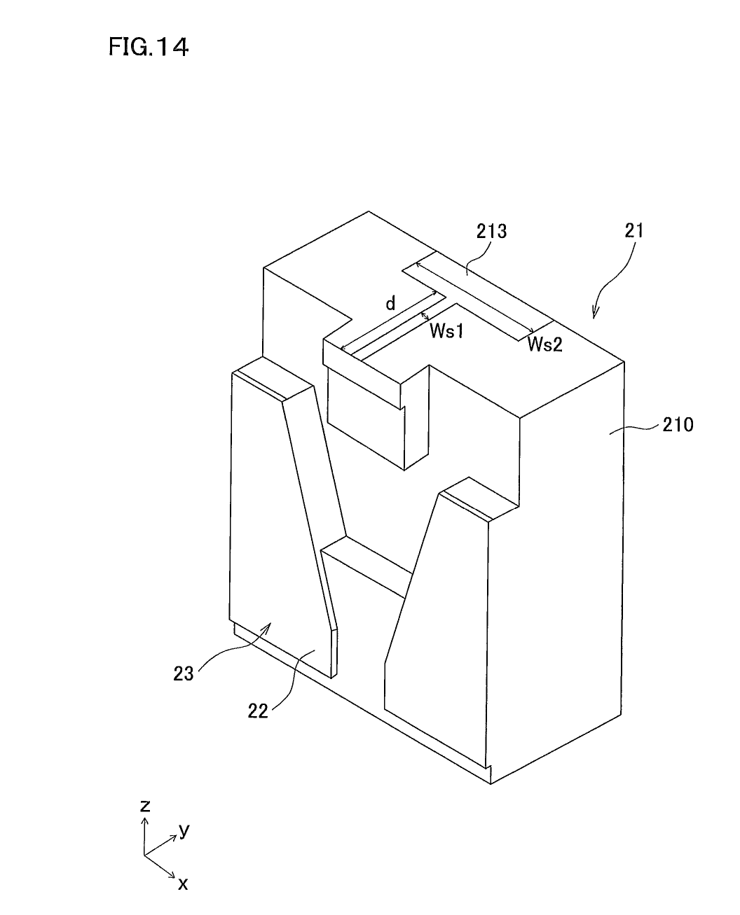

As shown in FIG. 14, the metal adhesive layer, the metal wiring layer, and the fusing metal layer 213 have two regions which are different in width in the x direction. Provided that the shorter width is Ws1 and the longer width is Ws2, Ws1 is shorter than the distance between unillustrated two height adjustment components of a later-described semiconductor laser device 13. Since the region with the width Ws2 functions as a pad for the connection with an external power source, Ws2 is preferably longer than Ws1. The length d of the region with the shorter width Ws1 is longer in the y direction than the length of the resonator of the semiconductor laser device 13.

The material of the ceramic substrate 210 preferably excels in anti-shock property, abrasion resistance, and heat conduction. The most preferable material is AlTiC which is typically used for consumer hard disc magnetic heads. The substrate 210 may be made of a material different from AlTiC; the material may be resin or ceramics such as zirconium. When the substrate of the supporter 21 of the present invention is made of AlTiC, it is possible to realize a recording head in which the semiconductor laser device 13 is highly precisely and easily aligned with the supporter 21 in the direction in which these components oppose each other (i.e. in the z direction).

The supporter 21 has a substantially rectangular shape, and sized 0.70 mm (x direction)×0.23 mm (y direction)×0.85 mm (z direction). The bottom surface 22 of the supporter 21 which surface is in parallel to the xz plane is provided with an ABS (Air Bearing Surface) structure 23 which is typically provided in consumer hard disc magnetic heads. This adjusts the flying height on a rapidly-rotating magnetic disc. The ABS structure 23 is formed by ion milling, for example. The shape of the ABS structure 23 is suitably determined in consideration of a desired flying height and disc tracking capability.

<Near-Field Light Generator>

Now, the near-field light generator will be described with reference to FIG. 15. As shown in FIG. 15, the near-field light generator 70 is composed of an insulating film 701 and a scatterer 702 which is a metal film formed on the insulating film 701. Viewed in the y direction, the scatterer 702 looks like a stick having arcs 703 and 704 at both ends and extending in the x direction. The long axis direction (x direction) of the scatterer 702 is in parallel to the polarization direction of laser light emitted from the semiconductor laser device 13. On the xz in-plane, the length of the scatterer 702 in the long axis direction (i.e. the length from the apex of the arc 703 to the apex of the arc 704) is 100 nm, the length in the short axis direction (z direction) is 25 nm, and the curvature radius of each of the arc 703 and 704 is 12.5 nm.

The insulating film 701 has a stepped surface 705. Furthermore, on the left and right of the stepped surface 705, an upper surface portion 706 and an lower surface portion 707 are formed, respectively. The stepped surface 705 is inclined at 45 degrees. The height difference between the upper surface portion 706 and the lower surface portion 707 is 30 nm.

One arc 704 of the scatterer 702 is provided on the upper surface portion 706, whereas the other arc 703 is provided on the lower surface portion 707. The arcs 703 and 704 are provided to overlap the center of the active layer 103 in the thickness direction of the layer. For efficient surface plasmon excitation and near-field light generation, both of the arc 703 and 704 are preferably provided to overlap the active layer 103.

From the facet mirror 122 of the semiconductor laser device 13, light polarized in the x direction is emitted toward the near-field light generator 70. As the near-field light generator 70 receives the light polarized in the x direction, surface plasmon resonance occurs in the scatterer 702, with the result that intense near-field light is generated at the arcs 703 and 704.

The aforesaid material, shape, and disposition of the scatterer 702 are determined in consideration of the wavelength of a desired near-field light and the conditions of excitation of surface plasmon in the near-field light generation area, and hence they may be differently arranged. For example, the material of the scatterer 702 is preferably gold when receiving red light having the wavelength of 650 nm typically used for DVDs, whereas the material is preferably silver when receiving light having the wavelength of 405 nm typically used for Blu-Ray discs. The design method for determining the above is, for example, FDTD (Finite Difference Time Domain) which is typically used for designing optical devices.

Since in the optical component 5 the semiconductor laser device 13 includes the near-field light generator 70, it is possible to realize a recording head including the near-field light generator 70.

<Magnetic Field Generator>

The magnetic field generator 80 is provided on the insulating film 701. The magnetic field generator 80 constituted by the conductive layer 708 has a C-shape to surround the scatterer 702. The both ends of the conductive layer 708 are connected to an external power source which is not illustrated, thereby allowing the conductive layer 708 to receive a current.

As a current in the direction indicated by the arrow I1 is applied to the conductive layer 708, a magnetic field extending in the directions indicated by three arrows H1 is generated around the scatterer 702 according to Ampere's law. The semiconductor laser device 13 in which the near-field light generator 70 is combined with the magnetic field generator 80 is joined with the supporter 21 by the method recited in one of First Embodiment to Third Embodiment, and these components are aligned to have substantially the same height as the surface (xz surface) of the arc 704 of the scatterer 702 and the outermost surface (xz surface) of the bottom surface 22.

In the present embodiment, the magnetic field generator 80 constituted by the conductive layer 708 is provided near the near-field light generator 70. It is therefore possible to generate an intense magnetic field around the arc 704. This makes it possible to locally generate both light and a magnetic field by supplying a current to the semiconductor laser device 13 and at the same time supplying a current to the conductive layer 708, and hence the optical component 5 functions as a near field light assisted magnetic recording device.

<Magnetic Field Reproduction Device>

In the supporter 21, a magnetic field reproduction device 90 is formed near the semiconductor laser device 13. This magnetic field reproduction device 90 is a GMR head or TMR head typically used in consumer hard disc drives, and is able to read out magnetic information by detecting the orientation of a magnetic field.

The optical component 5 of the present embodiment allows a recording head supporter which has been commercially used for hard disc drives to be easily aligned and joined with a semiconductor laser device with a simple process, thereby making it possible to realize a near field light assisted magnetic recording reproduction head which excels in anti-shock property, abrasion resistance, mass productivity, and reliability.

<Other Modifications>

Now modifications of the embodiments above will be described. It is noted that the same reference numerals are assigned to components having substantially identical arrangements as those of the embodiments above, and a repeated explanation is suitably avoided.

The embodiments above are arranged so that a height adjustment component for the adjustments in the z direction of the semiconductor laser device and the supporter are provided in the semiconductor laser device. Alternatively, a height adjustment component may be provided in the supporter. Furthermore, the shape of the height adjustment component can be variously modified as long as its end face is flat.

Fourth Embodiment is arranged so that the semiconductor laser device which is an optical device is used in place of the supporter 20 and the optical component is formed by joining two semiconductor laser devices with each other. Alternatively, the optical component may be formed by joining the semiconductor laser device with another optical device.

Fifth Embodiment is arranged so that the near-field light generator 70 and the magnetic field generator 80 are formed in the semiconductor laser device 13. Alternatively, the near-field light generator 70 and the magnetic field generator 80 may be formed in the supporter 21.

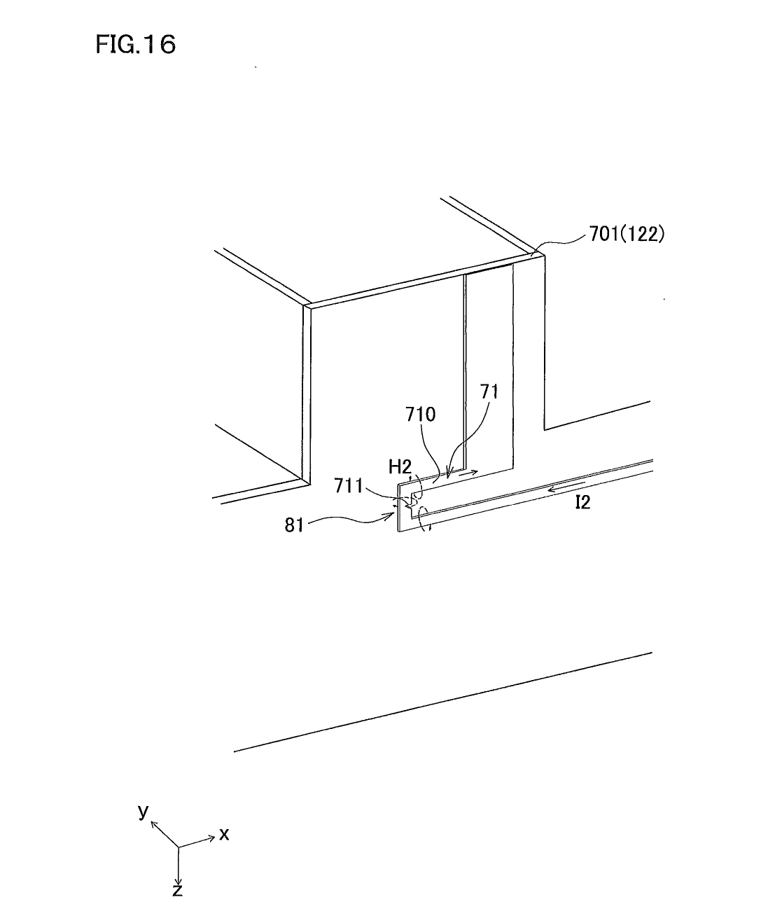

Fifth Embodiment may be arranged so that a near-field light generator 71 and a magnetic field generator 81 shown in FIG. 16 may be provided in place of the near-field light generator 70 and the magnetic field generator 80. The near-field light generator 71 is constituted by an insulating film 701 and a conductive layer 710 which is a metal film formed on the insulating film 701. The conductive layer 701 has a narrowed portion 711 which is a substantially triangular notch. This narrowed portion 711 is formed by lithography or lift-off patterning. The apex of the narrowed portion 711 is arranged to overlap the active layer of the semiconductor laser device 13.

The materials, shapes, and dispositions of the conductive layer 710 and the narrowed portion 711 are determined so that surface plasmon is efficiently excited in response to the emission wavelength of the semiconductor laser device 13, in the same manner as the near-field light generator 70 of Fifth Embodiment. As the light emitted from the semiconductor laser device 13 reaches the narrowed portion 711, surface plasmon is excited on the conductive layer 701 near the narrowed portion 711, and hence electric field concentration occurs at the apex of the narrowed portion 711. Around the apex of the narrowed portion 711, intense near-field light is generated due to the aforesaid electric field concentration. The region where the intense near-field light is generated is about as large as the curvature radius of the aforesaid apex of the narrowed portion 711.

The near-field light generator 71 also functions as the magnetic field generator 81. As the conductive layer 710 receives a current whose direction is indicated as 12 in FIG. 16, a magnetic field is generated to surround the conductive layer 710. The size of the surrounding magnetic field depends on the current density. The higher the current density is, the larger the generated magnetic field is. The conductive layer 710 around the apex of the narrowed portion 711 is smaller than the other regions in cross section because of the narrowed portion 711. The current density around the apex of the narrowed portion 711 is therefore higher than the intensity in the other regions, and an intense magnetic field H2 is generated around the apex of the narrowed portion 711, in particular.

Because the near-field light generator 71 and the magnetic field generator 81 are arranged as above, it is possible to locally generate both near-field light and a magnetic field around the apex of the narrowed portion 711, and to allow the optical component to function as a near field light assisted magnetic recording device.

In Fifth Embodiment, the present invention is directed to an optical component which includes a recording head supporter typically used in hard disk drives or the like and a semiconductor laser device joined with the supporter. Apart from this, the present invention is applicable to various uses such as laser pointers, photocopiers, and laser printers.

While this invention has been described in conjunction with the specific embodiments outlined above, it is evident that many alternatives, modifications and variations will be apparent to those skilled in the art. Accordingly, the preferred embodiments of the invention as set forth above are intended to be illustrative, not limiting. Various changes may be made without departing from the spirit and scope of the invention as defined in the following claims.

What is claimed is:

1. An optical component comprising a supporter and a semiconductor laser device supported by the supporter, wherein,
the supporter includes a substrate, a metal wiring layer formed over the substrate, and a fusing metal layer formed on the metal wiring layer,
the semiconductor laser device includes: stacked semiconductor films including an active layer; and an electrode formed on the stacked semiconductor films,
one of the supporter and the semiconductor laser device has a protrusion and an end face of the protrusion is in area contact with the other one of the supporter and the semiconductor laser device, and
the metal wiring layer is integrated with the electrode via the fusing metal layer, at a location different from the protrusion.

2. The optical component according to claim 1, wherein,
the end face of the protrusion is a flat surface in parallel to an in-plane direction of the stacked semiconductor films.

3. The optical component according to claim 1, wherein,
the semiconductor laser device has a ridge which protrudes toward the fusing metal layer and confines light in an in-plane direction of the stacked semiconductor films, and
the protrusion is formed so as not to overlap the ridge, when viewed in a direction orthogonal to the in-plane direction.

4. The optical component according to claim 3, wherein,
the protrusion and the ridge include a same one of the stacked semiconductor films, and a part of said one semiconductor film which part is included in the protrusion is at the same height as another part of said one semiconductor film which part is included in the ridge.

5. The optical component according to claim 1, wherein,
when viewed in a direction orthogonal to an in-plane direction of the stacked semiconductor films, the protrusion partly overlaps the electrode of the semiconductor laser device.

6. The optical component according to claim 1, wherein,
one of the supporter and the semiconductor laser device includes a near-field light generator which generates near-field light based on light emitted from the semiconductor laser device.

7. The optical component according to claim 6, wherein,
one of the supporter and the semiconductor laser device includes a magnetic field generator.

8. The optical component according to claim 6, wherein,
one of the supporter and the semiconductor laser device includes a magnetic field detector.

9. The optical component according to claim 1, wherein,
the substrate of the supporter is made of AlTiC which is a ceramic material.

10. The optical component according to claim 1, wherein,
the supporter is a part of an optical device which is different from the semiconductor laser device.

11. The optical component according to claim 10, wherein,
the optical device including the supporter is another semiconductor laser device, the semiconductor laser device and said another semiconductor laser device emit light with different wavelengths.

12. A method of manufacturing an optical component including a supporter and a semiconductor laser device supported by the supporter, the method comprising the steps of:
(i) forming the supporter;
(ii) forming the semiconductor laser device; and
(iii) joining the supporter with the semiconductor laser device, wherein,
the step (i) includes sub-steps of:
(a) forming a metal wiring layer over the substrate; and
(b) forming a fusing metal layer on the metal wiring layer,
the step (ii) includes sub-steps of:
(c) stacking a plurality of semiconductor films including an active layer;
(d) on the semiconductor films, forming a ridge which includes an electrode and confines light in an in-plane direction of the semiconductor films; and
(e) forming a protrusion on the semiconductor films, the protrusion being higher than the ridge,
in the sub-step (e), the protrusion is formed in such a way that, when the semiconductor laser device is disposed with respect to the supporter to cause an end face of the ridge to contact the fusing metal layer, the protrusion is distanced from the supporter by a distance shorter than the thickness of the fusing metal layer, and
in the step (iii), the supporter and the semiconductor laser device are heated to a temperature higher than a melting temperature of the fusing metal layer while the semiconductor laser device is disposed with respect to the supporter to make the end face of the ridge to contact the fusing metal layer and the supporter and the semiconductor laser device are pressed against each other, with the result that the metal wiring layer is integrated with the electrode via the fusing metal layer and the end face of the protrusion is in area contact with the supporter.
